(19) United States
(12) Patent Application Publication
(10) Pub. No.: US 2022/0274535 A1
(43) Pub. Date: Sep. 1, 2022

(54) Angle-adjustable vehicle-mounted display bracket

(71) Applicant: Dongguan Omuda Auto Parts Co., Ltd., Dongguan (CN)

(72) Inventor: Chunming Zhong, Dongguan (CN)

(21) Appl. No.: 17/748,082

(22) Filed: May 19, 2022

(30) Foreign Application Priority Data
Apr. 15, 2022 (CN) 2022208887583

(51) Int. Cl. B60R 11/02; B60K 35/00

(52) U.S. Cl. CPC B60R 11/0235; B60K 35/00; B60R 2011/0005

(57) ABSTRACT

Disclosed is an angle-adjustable vehicle-mounted display bracket, which comprises two fixed parts fixed on a frame, connecting parts fixedly connected to the fixed parts, a pivot shaft rotatably penetrating between the two connecting parts, and a swing frame penetrating the pivot shaft and swinging relative to the pivot shaft, wherein a display is fixedly installed on the swing frame; a first limiting mechanism is arranged between the connecting parts and the pivot shaft to limit the adjustment of the pitch angle of the display; and a second limiting mechanism is arranged between the pivot shaft and the swing frame to limit the amplitude of the left-right swing of the display. After the display is fixed, the angle-adjustable vehicle-mounted display bracket can simultaneously realize the pitch adjustment and the left-right swing adjustment, thus realizing the adjustment requirements in two directions, overcoming the disadvantage that the existing stand-type display can only perform the pitch adjustment, and meeting the actual use requirements.

### TECHNICAL FIELD

The present invention relates to an angle-adjustable vehicle-mounted display bracket.

### BACKGROUND

A vehicle-mounted display is a kind of display installed in the cab, which is used to assist driving such as navigation or as a multimedia device. With the development of the automobile industry, nowadays, vehicle-mounted displays are generally installed in the cab of family cars. According to different mounting forms, vehicle-mounted displays can be divided into two types, one is embedded-type, and the other is bracket-type. The embedded display is embedded in the front desk of the cab, which is integrated with the front desk of the cab, while the bracket-type display is installed and fixed by the bracket, which can generally be adjusted for pitch. Most of the existing stand displays can only adjust the pitch, while the displays are generally installed in the middle of the front desk of the cab. When the light changes, it is difficult for drivers to read the display information, which affects driving safety.

### SUMMARY

In view of the shortcomings of the above problems, the present invention provides an angle-adjustable vehicle-mounted display bracket.

In order to achieve the above purpose, the present invention provides an angle-adjustable vehicle-mounted display bracket, which includes two fixed parts fixed on a frame, connecting parts fixedly connected to the fixed parts, a pivot shaft rotatably penetrating between the two connecting parts, and a swing frame penetrating the pivot shaft and swinging relative to the pivot shaft, wherein a display is fixedly installed on the swing frame; a first limiting mechanism is arranged between the connecting parts and the pivot shaft to limit the adjustment of the pitch angle of the display; and a second limiting mechanism is arranged between the pivot shaft and the swing frame to limit the amplitude of the left-right swing of the display.

After the display is fixed, the angle-adjustable vehicle-mounted display bracket can simultaneously realize the pitch adjustment and the left-right swing adjustment, thus realizing the adjustment requirements in two directions, overcoming the disadvantage that the existing stand-type display can only perform the pitch adjustment, and meeting the actual use requirements.

As a further improvement of the solution, the fixed parts are hollow tubes with square cross sections, two hollow tubes are arranged in parallel, the connecting parts are inserted into the hollow tubes and locked by bolts, the connecting parts are provided with first through holes, and two ends of the pivot shaft are provided with first screws passing through the first through holes to form a relative rotation structure;

In the technical solution, the fixed parts are hollow pipes, and the connecting parts are inserted into the hollow pipes, so that the connection is convenient, and the problems of space limitation and inconvenient assembly of the front desk of the cab are overcome.

As a further improvement of the solution, the connecting part is provided with a first mounting groove for mounting a rubber ring;

In the technical solution, the rubber ring is arranged at the first mounting groove, and the rubber ring tightly fits the connecting part and the pivot shaft through elastic action, so that the pivot shaft does not rotate freely under the condition of no artificial operation.

As a further improvement of the solution, the pivot shaft is provided with a second through hole, and the lower part of the swing frame is provided with a second screw passing through the second through hole to form a swingable structure;

in the technical solution, the connection between the swing frame and the pivot shaft is convenient, and the assembly is efficient.

As a further improvement of the solution, the swing frame is provided with a second mounting groove for mounting a rubber ring;

in the technical solution, the rubber ring is arranged at the second mounting groove, and the rubber ring tightly fits the pivot shaft and the swing frame through the elastic action, so that the swing frame does not swing freely under the condition of no artificial operation.

As a further improvement of the solution, the first limiting mechanism includes a first adjusting groove provided on the side of the pivot shaft, and the connecting part has a first convex column extending into the first adjusting groove, and the first convex column interacts with the first adjusting groove to limit the angle of the up-and-down rotation of the pivot shaft to 40 degrees;

In the technical solution, the first convex column and the first adjusting groove are used to limit the pitch angle, so as to meet the requirement of pitch angle adjustment.

As a further improvement of the solution, the second limiting mechanism includes a second adjusting groove processed on the pivot shaft, and the swing frame has a second convex column extending into the second adjusting groove, and the second convex column interacts with the second adjusting groove to limit the angle of the left and right swing of the swing frame to 40 degrees;

in the technical solution, the limit is realized by the action of the second convex column and the second adjusting groove, and the requirement for adjusting the left-and-right swing angles is met.

As a further improvement of the solution, the rear part of the display is also fixed with a shield, which is provided with an extension plate, and the extension plate extends to the neck position of the swing frame;

in the technical solution, the configuration of the shield ensures the beauty of the connecting part between the display and the swing frame, and the extension plate further strengthens the structure.

As a further improvement of the solution, it also includes an outer cover, and the outer cover is connected to the front desk of the cab in a buckle way, has an opening through which the swing frame can penetrate, and hides the fixed part and the connecting part inside the front desk of the cab;

in the technical solution, the outer cover hides most parts, which meets the aesthetic requirements.

Compared with the prior art, the present invention has the beneficial effects that: after the display is fixed, the angle-adjustable vehicle-mounted display bracket can simultaneously realize the pitch adjustment and the left-right swing adjustment, thus realizing the adjustment requirements in two directions, overcoming the defect that the existing bracket display can only perform the pitch adjustment, and meeting the actual use requirements; the angle-adjustable vehicle-mounted display bracket is compact and reasonable in structural design, convenient to assemble, and convenient to adjust the pitch and swing.

### BRIEF DESCRIPTION OF DRAWINGS

FIG. 1 is a perspective view of an angle-adjustable vehicle-mounted display bracket of the present invention;

FIG. 2 is a perspective view of an angle-adjustable vehicle-mounted display bracket of the present invention;

FIG. 3 is an exploded view of an angle-adjustable vehicle-mounted display bracket of the present invention;

FIG. 4 is a schematic view of the swing frame in FIG. 3 in another direction;

FIG. 5 is a schematic diagram of a display and a protective cover arranged on the angle-adjustable vehicle-mounted display bracket;

FIG. 6 is a schematic diagram of the configuration of the outer cover based on FIG. 5.

In the figures: 1. Fixed parts; 2. Bolts; 3. Connecting parts; 31. First convex column; 32. First mounting groove; 4. First screw; 5. Pivot shaft; 51. First adjusting groove; 52. Second adjusting groove; 6. Second screw; 7. Swing; 71. Second convex column; 72. Second mounting groove; 8. Display; 9. Shield; 91. Extension plate; 10. Outer cover.

### DESCRIPTION OF EMBODIMENTS

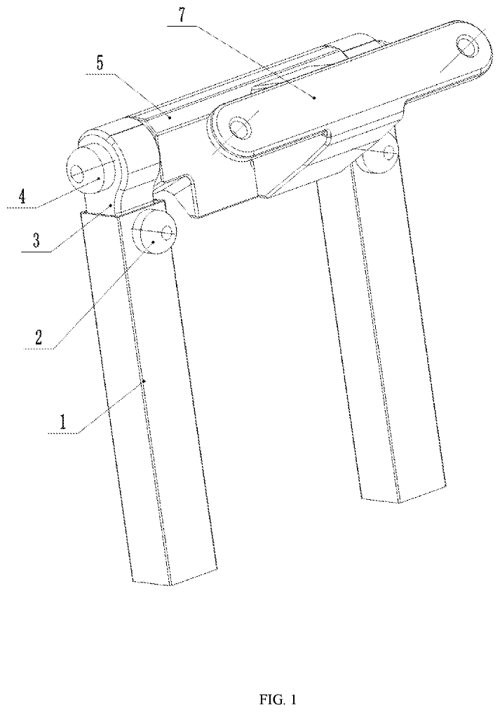

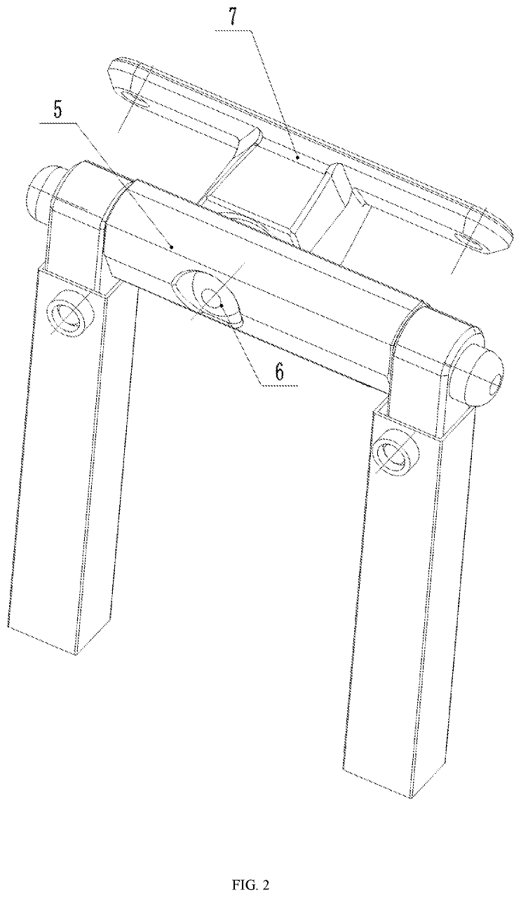

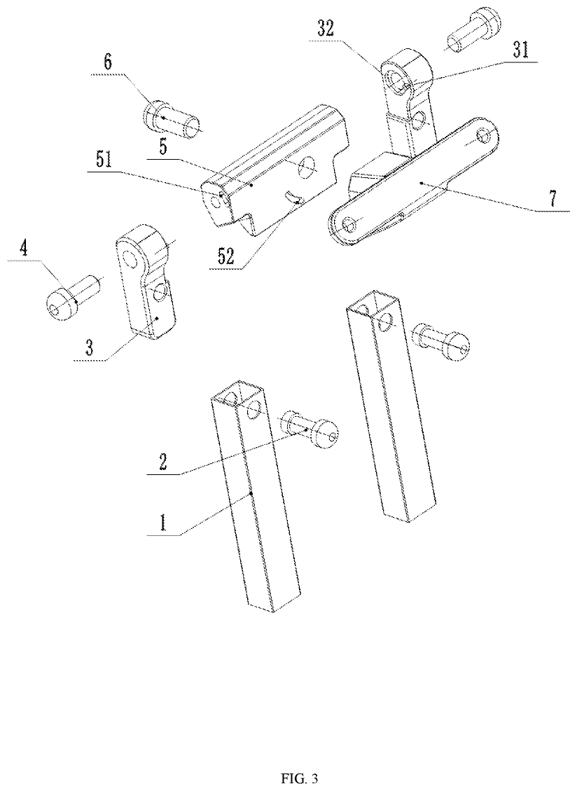

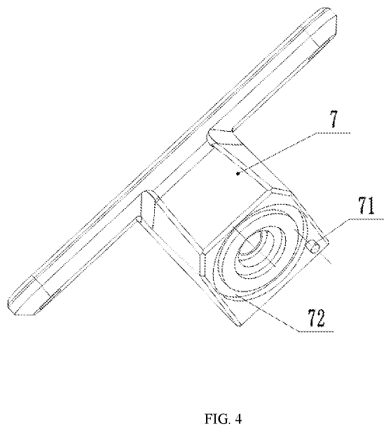

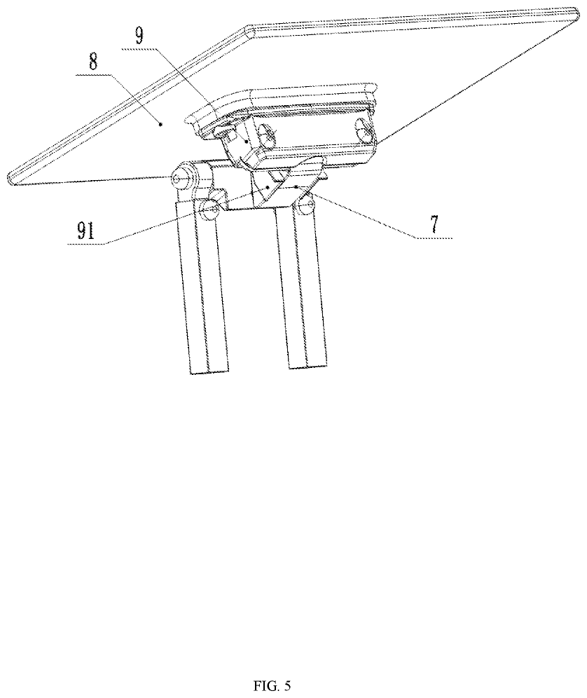

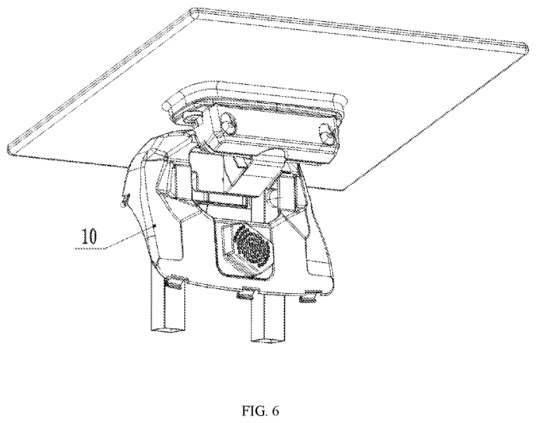

As shown in FIGS. 1-6, an angle-adjustable vehicle-mounted display bracket according to the embodiment of the present invention includes two fixed parts 1 fixed on a frame, connecting parts 3 fixed on the fixed parts 1, a pivot shaft 5 rotatably inserted between the two connecting parts 3, and a swing frame 7 inserted on the pivot shaft 5 and capable of swinging relative to the pivot shaft 5. A display 8 is fixedly mounted on the swing frame 7, and a first limiting mechanism is arranged between the connecting part 3 and the pivot shaft 5 to limit the adjustment of the pitch angle of the display 8. A second limiting mechanism is arranged between the pivot shaft 5 and the swing frame 7 to limit the amplitude of the left-right swing of the display 8. Wherein, the fixed part 1 is a hollow tube with a square cross section, two hollow tubes are arranged in parallel, the connecting part 3 is inserted into the hollow tube and locked by a bolt 2, the connecting part 3 is provided with a first through hole, and the two ends of the pivot shaft 5 are provided with first screws 4 passing through the first through hole to form a relative rotation structure; the fixed part is a hollow tube, and the connecting part is inserted into the hollow tube, so that the connection is convenient, and the problems of space limitation and inconvenient assembly of the front desk of the cab are overcome; the connecting part 3 is provided with a first mounting groove 32 for mounting a rubber ring, and the rubber ring is arranged at the first mounting groove, so that the connecting part is tightly matched with the pivot shaft through the elastic action, and the pivot shaft does not rotate freely under the non-human operation; the pivot shaft 5 is provided with a second through hole, and the lower part of the swing frame 7 is provided with a second screw 6 passing through the second through hole to form a swingable structure, so that the swing frame and the pivot shaft are connected conveniently and efficiently, and the assembly is efficient; the swing frame 7 is provided with a second mounting groove 72 for mounting a rubber ring, and the rubber ring is arranged at the second mounting groove, so that the pivot shaft and the swing frame are tightly matched through elastic action, thus ensuring that the swing frame does not swing freely under artificial operation; the first limiting mechanism includes a first adjusting groove 51 provided on the side of the pivot shaft 5, and the connecting part 3 has a first convex column 31 extending into the first adjusting groove 51. The first convex column 31 acts with the first adjusting groove 51 to limit the angle of up-and-down rotation of the pivot shaft 5 to 40 degrees, and the limit is realized by the action of the first convex column and the first adjusting groove, so as to meet the requirement of pitch angle adjustment. The second limiting mechanism includes a second adjusting groove 52 processed on the pivot shaft 5, and the swing frame 7 has a second convex column 71 extending into the second adjusting groove 52. The second convex column 71 acts with the second adjusting groove 52 to limit the swinging angle of the swing frame 7 to 40 degrees, and the limit is realized by the action of the second convex column and the second adjusting groove, so as to meet the requirements for adjusting the swinging angle. The rear part of the display 8 is also fixed with a shield 9, which has an extension plate 91 extending to the neck of the swing frame 7. The configuration of the shield ensures the beauty of the connection part between the display and the swing frame, and the extension plate further strengthens the structure. The angle-adjustable vehicle-mounted display bracket also includes an outer cover 10, which is buckled on the front desk of the cab and has an opening through which the swinging bracket 7 can penetrate. The outer cover 10 hides the fixed part 1 and the connecting part 3 inside the front desk of the cab, and hides most parts, which meets the aesthetic requirements.

After the display is fixed, the angle-adjustable vehicle-mounted display bracket can simultaneously realize the pitch adjustment and the left-right swing adjustment, thus realizing the adjustment requirements in two directions, overcoming the disadvantage that the existing stand-type display can only perform the pitch adjustment and meeting the actual use requirements; the angle-adjustable vehicle-mounted display bracket is compact and reasonable in structural design, convenient to assemble, and convenient to adjust the pitch and swing.

The above is only the preferred embodiment of the present invention, and it is not intended to limit the present invention. For those skilled in the art, the present invention can be modified and varied. Any modification, equivalent substitution, improvement, etc. made within the spirit and principle of the present invention shall be included in the scope of protection of the present invention.

What is claimed is:

1. An angle-adjustable vehicle-mounted display bracket, comprising two fixed parts fixed on a frame, connecting parts fixedly connected to the fixed parts, a pivot shaft rotatably penetrating between the two connecting parts, and a swing frame penetrating the pivot shaft and swinging relative to the pivot shaft, wherein a display is fixedly arranged on the swing frame, a first limiting mechanism is arranged between the connecting parts and the pivot shaft to limit the adjustment of a pitch angle of the display, and a second limiting mechanism is arranged between the pivot shaft and the swing frame to limit an amplitude of the left and right swing of the display.

2. The angle-adjustable vehicle-mounted display bracket according to claim 1, wherein the fixed parts are hollow tubes with square cross sections, the two hollow tubes are arranged in parallel, the connecting parts are inserted into the hollow tubes and locked by bolts, the connecting parts are provided with first through holes, and two ends of the pivot shaft are provided with first screws passing through the first through holes to form a relative rotation structure.

3. The angle-adjustable vehicle-mounted display bracket according to claim 2, wherein the connecting part is provided with a first mounting groove for mounting a rubber ring.

4. The angle-adjustable vehicle-mounted display bracket according to claim 1, wherein the pivot shaft is provided with a second through hole, and a lower part of the swing frame is provided with a second screw passing through the second through hole to form a swingable structure.

5. The angle-adjustable vehicle-mounted display frame according to claim 4, wherein the swing frame is provided with a second mounting groove for mounting a rubber ring.

6. The angle-adjustable vehicle-mounted display bracket according to claim 1, wherein the first limiting mechanism comprises a first adjusting groove provided at the side of the pivot shaft, and the connecting part has a first convex column extending into the first adjusting groove, and the first convex column interacts with the first adjusting groove to limit an angle of the up-and-down rotation of the pivot shaft to forty degrees.

7. The angle-adjustable vehicle-mounted display bracket according to claim 1, wherein the second limiting mechanism comprises a second adjusting groove provided on the pivot shaft, and the swing frame has a second convex column extending into the second adjusting groove, and the second convex column interacts with the second adjusting groove to limit an angle of the left-to-right swing of the swinging frame to forty degrees.

8. The angle-adjustable vehicle-mounted display bracket according to claim 1, wherein a shield is further fixed to the rear of the display, and the shield is provided with an extension plate which extends to the neck of the swing frame.

9. The angle-adjustable vehicle-mounted display bracket according to claim 1, further comprising an outer cover, which is connected to a front desk of a cab in a buckle way, and the outer cover has an opening through which the swing frame penetrates, and the outer cover hides the fixed parts and the connecting parts inside the front desk of the cab.
